(19) United States
(12) Patent Application Publication
(10) Pub. No.: US 2008/0237871 A1
(43) Pub. Date: Oct. 2, 2008

(54) Method of Manufacturing a Semiconductor Device and Semiconductor Device Obtained With Such a Method

(75) Inventors: Vijayaraghavan Madakasira, Louvain (BE); Prabhat Agarwal, Brussels (BE); Johannes Josephus Theodorus Marinus Donkers, Valkenswaard (NL); Mark Van Dal, Heverlee (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/093,649

(22) PCT Filed: Oct. 27, 2006
(86) PCT No.: PCT/IB06/53956

§ 371 Date: May 21, 2008

(30) Foreign Application Priority Data
Nov. 16, 2005 (EP) 05110788.6

(51) Int. Cl. H01L 21/768; H01L 21/20; H01L 23/532

(52) U.S. Cl. 257/768; 438/664; 438/486; 257/E21.585; 257/E21.09; 257/E23.157

(57) ABSTRACT

The invention relates to a method of manufacturing a semiconductor device (10) with a substrate (11) and a semi-conductor body (12) which is provided with at least one semiconductor element (E) and comprising a monocrystalline silicon (1) region on top of which an epitaxial silicon region (2) is formed by providing a metal silicide region (3) on the monocrystalline silicon region (1) and a low-crystallinity silicon region (4) on top of the metal silicide region (3), after which the low-crystallinity silicon region (4) is transformed by heating into the epitaxial silicon region (2) having a high-crystallinity, during which process the metal silicide region (3) is moved from the bottom of the low-crystallinity silicon region (4) to the top of the epitaxial silicon region (2). According to the invention above the level of the metal silicide region (3) an insulating layer (5) is formed which is provided with an opening (6), the low-crystallinity silicon region (4) is deposited in the opening (6) and on top of the insulating layer (5), the part (4A, 4B) of the low-crystallinity silicon region (4) on top of the insulating layer (5) is removed by a planarization process after which the epitaxial silicon region (2) is formed. In this way an epitaxial silicon region (2), preferably a nano wire (2), is simply obtained that is provided with a metal silicide contact (region) in a self-aligned manner and that can form a part of semiconductor element (E) like a transistor.

The invention relates to a method of manufacturing a semiconductor device with a substrate and a semiconductor body which is provided with at least one semiconductor element and comprising a monocrystalline silicon region on top of which an epitaxial silicon region is formed by providing a metal silicide region on the monocrystalline silicon region and a low-crystallinity silicon region on top of the metal silicide region, after which the low-crystallinity silicon region is transformed into the epitaxial silicon region having a higher crystallinity by heating, during which process the metal silicide region is moved from the bottom of the low-crystallinity silicon region to the top of the epitaxial silicon region. The invention also relates to a semiconductor device obtained with such a method. Low and high in relation to the crystallinity nature refers to the degree of crystallinity.

Such a method is very suitable for making semiconductor devices like ICs (=Integrated Circuit) comprising various semiconductor elements like transistors and diodes. However, other devices such as discrete devices are obtainable as well by such a method.

A method as mentioned in the opening paragraph is known from “Modeling of Grain Growth Mechanism by Nickel Silicide Reactive Grain Boundary Effect in Metal-Induced-Lateral-Crystallization” by C. F. Cheng et al., that has been published in IEEE Transactions on Elecron Device, vol. 50, no. 6, June 2003, pp 1467-1474. Therein it is shown, e.g. in FIG. 3, how an epitaxial silicon region is grown from an amorphous silicon region on top of a nickel silicide region that is formed on a monocrystalline silicon substrate. In this publication it is mentioned that amorphous silicon is transformed into polycrystalline silicon by a (lateral) crystallization process. The resulting epitaxial silicon is used to form TFT (=Thin Film Transistor) devices.

It is to be noted that in the present patent application low-crystallinity is intend to comprise both amorphous silicon and polycrystalline silicon. If the low-crystallinity silicon comprising amorphous silicon is transformed into the epitaxial silicon region having the higher crystallinity, this means that the amorphous silicon either becomes polycrystalline or mono-crystalline. If the low-crystallinity silicon comprising polycrystalline silicon is transformed into the epitaxial silicon region having the higher crystallinity, this means that the polycrystalline silicon becomes mono-crystalline.

A drawback of such a method is that its integration with standard (monocrystalline) silicon technology is seriously hampered by the presence of the metal silicide region on top of the epitaxial silicon region. This is caused by the fact that the metal silicide region cannot easily be etched and thus removal thereof is difficult.

It is therefore an object of the present invention to avoid the above drawback and to provide a method which is very compatible with standard silicon technology.

To achieve this, a method of the type described in the opening paragraph is characterized in that above the level of the metal silicide region an insulating layer is formed which is provided with an opening, the low-crystallinity silicon region is deposited in the opening and on top of the insulating layer, the part of the low-crystallinity silicon region on top of the insulating layer is removed by a planarization process after which the epitaxial silicon region is formed. The invention is firstly based on the recognition that it is not necessary to completely remove the metal silicide on top of the epitaxial silicon region since parts thereof could be used to contact certain parts of the epitaxial silicon region. The invention is further based on the recognition that patterning the metal silicide on top of the epitaxial silicon that still would require etching the metal silicide can be avoided by patterning the low-crystallinity silicon region before the epitaxial silicon region is formed. Finally, the invention is based on the recognition that by patterning the low-crystallinity silicon region by a damascene like technology, the resulting structure will have a planar insulating surface region comprising local epitaxial silicon region(s) that are provided in a self-aligned manner with the metal silicide region(s).

This method has advantages, in particular if the epitaxial silicon regions are in the form of a nano wire which is used as an interconnection via or which forms a part of a transistor, e.g. as a contact region for a source and/or drain region of a field effect transistor or as an emitter region or a collector region of an (inverted) bipolar transistor. In such a case the remaining parts of the semiconductor element—and possibly other semiconductor elements—are already formed in advance into the monocrystalline silicon region. The latter may be a part of the substrate, in case a monocrystalline silicon substrate or a substrate transfer technique is used or of an epitaxial layer-shaped region, in case of the use of a monocrystalline silicon substrate.

It is further noted that where in this application regions are referred to as being of silicon this also comprises that the regions may be of a mixed crystal of silicon and some other group IV-element in the periodic system, such as germanium.

In a preferred embodiment the metal silicide is formed by depositing a metal region at the location of the metal silicide to be formed which subsequently is transformed in a heating process in the metal silicide region by reacting with the underlying silicon. In this way, also at the beginning of the process etching of the metal silicide is avoided. This may be done by local deposition of the metal or by an overall deposition of the metal followed by photolithography and etching. The insulating layer may be formed on top of the metal silicide region after which an opening is etched in the insulating layer. If the lateral size of the metal silicide region is chosen to be (considerably) larger than the lateral size of the opening, aligning of the opening in the insulating layer with the metal silicide region becomes easy.

In a further preferred embodiment the metal region is formed by deposition of a metal layer after the formation of the insulating layer provided with the opening and after formation of the metal silicide region on the bottom of the opening, the remainder of the metal layer is removed by etching, preferably by selective etching.

Preferably the size of the opening in the insulating layer is chosen such that the epitaxial silicon region forms a nano wire. On the one hand nano wires are attractive for future devices and on the other hand providing such wires with a self-aligned metal silicide contact is not easy with conventional technology. It is to be noted that here with a nano wire a body is intended having at least one lateral dimension between 0.5 and 100 nm and more in particular between 1 and 50 nm. Preferably a nano-wire has dimensions in two lateral directions that are in the said ranges.

However, although the manufacturing is in particular suitable for the manufacturing of devices having or using a nano wire part, it may also be applied to (much) devices having or using larger mesa-shaped semiconductor regions.

In another preferred embodiment the epitaxial silicon region is formed as a part of the semiconductor element. As explained before the method may be in particular suitable for the manufacturing of a field effect transistor, wherein the epitaxial silicon region is used to form contact regions on top of the source and drain regions of the field effect transistor. This also holds for the manufacturing of a bipolar transistor wherein the epitaxial silicon region is used to form an emitter region or collector region of the bipolar transistor.

Preferably for the metal nickel or cobalt are chosen. These metals are very compatible with advanced silicon technology and result in very low-ohmic metal silicides. The opening in the insulating layer is preferably formed by e-beam lithography and dry etching. This is well compatible with advanced low size devices like those containing a nano wire.

A preferred process for the planarization process is CMP (=Chemical Mechanical Polishing).

The invention finally comprises also a semiconductor device obtained by a method according to the invention.

These and other aspects of the invention will be apparent from and elucidated with reference to the embodiments described hereinafter, to be read in conjunction with the drawing, in which

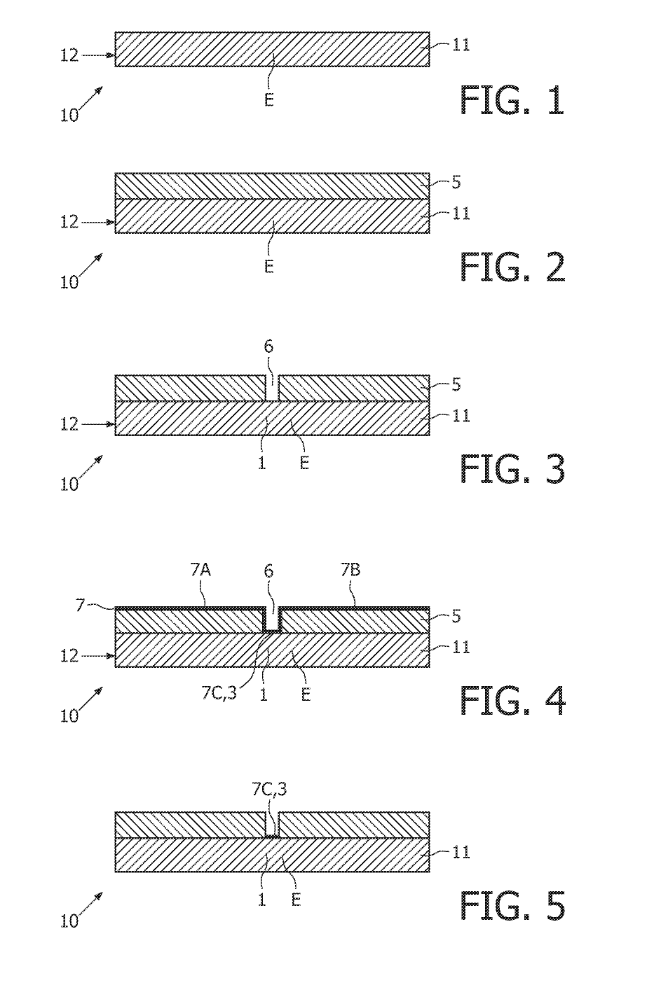

FIGS. 1 through 9 are sectional views of a semiconductor device at various stages in its manufacture by means of a method in accordance with the invention.

The Figures are diagrammatic and not drawn to scale, the dimensions in the thickness direction being particularly exaggerated for greater clarity. Corresponding parts are generally given the same reference numerals and the same hatching in the various Figures.

FIGS. 1 through 9 are sectional views of a semiconductor device at various stages in its manufacture by means of a method in accordance with the invention.

The semiconductor device manufactured in this example comprises as the semiconductor element E e.g. a field effect transistor or a bipolar transistor that may be formed in a usual manner. The epitaxial silicon region that is formed in the method of this example may be e.g. a contact structure for the source/drain region of field effect transistor or the emitter of a bipolar transistor the collector region in an inverted bipolar transistor. The features of such a transistor are for reasons of simplicity not shown in the drawing. It may be formed in part or completely before a first relevant step of the method according to the invention.

In the first relevant step of the manufacture of a device 10 (see FIG. 1) a first substrate 11, here a monocrystalline silicon substrate 11 and forming a semiconductor body 12 is provided with a semiconductor element E in a usual manner. The semiconductor body 12 may comprises an epitaxial silicon layer and a number of semiconducting, conducting and insulating regions which all are not shown in the drawing but are used to form and in the formation of the semiconductor element E.

Next (see FIG. 2) an insulating layer 5 is formed on top of the semiconductor body 12. In this example a silicon dioxide layer 5 is formed by a thermal oxidation and having a thickness of e.g. 500 nm, corresponding with a nano wire height/length.

In the insulating layer 5 (see FIG. 3) an opening 6 is formed. In this example this is done using e-beam photolithography and etching with a dry etch process. The mask used in the photolithography is not shown in the drawing but may be a special e-beam photo resist.

Subsequently (see FIG. 4) a metal layer 6, here comprising nickel and being 15 nm thick, is deposited, e.g. by vapor deposition or sputtering. The structure is then heated at a temperature in the range of 280 to 400° C., during e.g. 60 second, during which step the metal 7C that is present on the bottom of the opening 6 is transformed into metal silicide region 3 by reaction of the nickel 7C with the underlying monocrystalline silicon part 1 which in turn forms a part of the semiconductor body 12, here also of the semiconductor substrate 11.

Next (see FIG. 5), the remaining parts 7A,7B (See FIG. 4) of the metal layer 7, here of nickel, are removed by a wet etching step which is selective towards silicon dioxide. It is to be noted that said parts 7A,7B also include the parts of the metal layer 7 present on the walls of the opening 6.

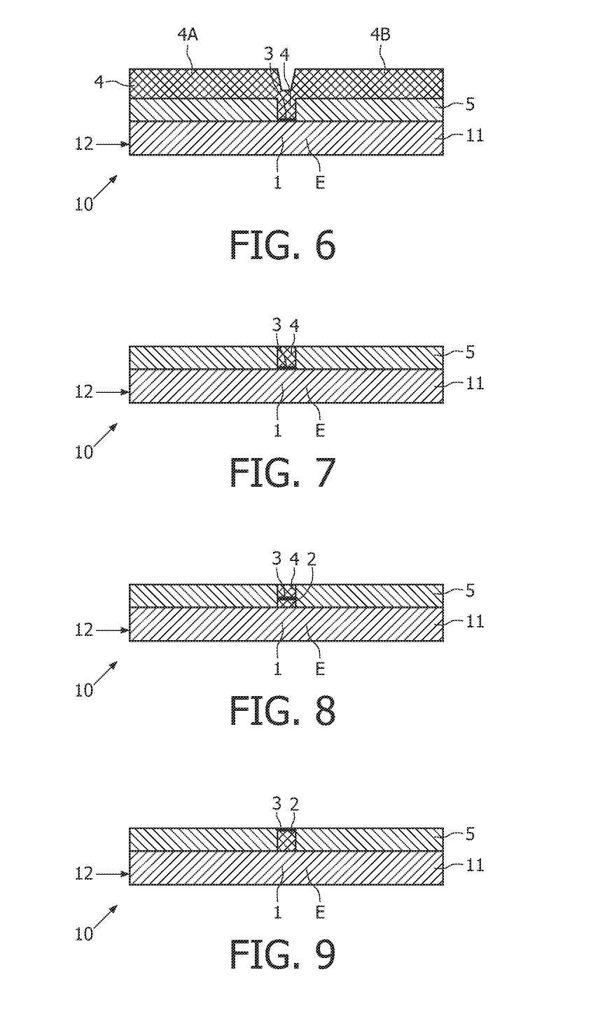

Subsequently (see FIG. 6), a polycrystalline silicon layer 4 is deposited over the structure using e.g. CVD (=Chemical Vapor Deposition). The thickness of the layer 4 is chosen such that the opening 6 is completely filled with a part of said layer forming low-crystallinity silicon region 4. Parts 4A,4B of the poly silicon layer 4 that are on top of the insulating layer 5 are hereinafter removed by applying a planarization process, in this example CMP.

The resulting structure (see FIG. 7) shows the low-crystallinity silicon region 4 sunken in the insulating layer 5 and on top of the nickel silicide region 3 present at a level (substantially) below the level of the insulating layer 5.

Now (see FIG. 8) the structure of FIG. 7 is subjected to a heating treatment, e.g. at a temperature in the range of 500 to 900° C., in this example at 500° C. in a furnace. By this treatment a process that is known as SPE (=Solid Phase Epitaxy) starts which is initiated and regulated/controlled by the present nickel silicide region 3. As shown in FIG. 8, the result of this is that after some time an epitaxial silicon region 2 having a higher degree of crystallinity is formed directly on top of a monocrystalline silicon part 1 below the insulating layer 5 while the remainder of the low-crystallinity silicon region 4—from which the epitaxial region 3 is formed—is present on top of the epitaxial region 3 and separated therefrom by the nickel silicide region 3.

At the end of this process (see FIG. 9), the epitaxial silicon region 2 completely fills the opening 6 in the silicon dioxide layer 5 and the nickel silicide region 3 is present on top of the epitaxial region 3 while the low-crystallinity region 4 is completely absent. Thus, in this way a mono (at least a high degree crystallinity) crystalline silicon nano wire 2 has been formed that is provided in a self aligned manner with a metal silicide contact region 3. As explained above the nano wire may be used to contact an underlying structure like the source and drain regions of a field effect transistor E, may form the emitter or collector of a bipolar transistor E.

Individual devices 10 that are suitable for mounting are obtained after applying a separation technique like etching or sawing. It will be obvious that the invention is not limited to the examples described herein, and that within the scope of the invention many variations and modifications are possible to those skilled in the art.

For example it is to be noted that, although described for the manufacture of a single epitaxial region, a large number of these regions may be manufactured at the same time. One or a plurality of such regions may be formed as functioning in a single element. The invention is applicable not only to the manufacture of discrete devices but also very suitable for the manufacture of ICs like (C)MOS or BI(C)MOS ICs but also for bipolar ICs.

Furthermore it is noted that various modifications are possible with respect to individual steps. For example instead of an insulating layer made by thermal oxidation, such layer may be formed by a deposition process like CVD. Also other dielectric materials like silicon nitride may be used for such a layer. The epitaxial region comprising silicon may comprise other materials like a mixed crystal of silicon and germanium.

In addition it is to be noted that since the method according to the invention in case of nano wires involves metal silicidation, it can be useful to grow a nano wire on the via of an inter metal dielectric, as in the BEOL (=Back End Of Line) process.

Moreover, an important advantage in case of the provision of one or more or a plurality of nano wires, these nano wires are obtained having a very uniform height because said height is equal to the thickness of the insulating layer and the latter can be very uniform. Also in such case of the provision of nano wires, whether or not a nano wire is present and if so, where it is positioned is very easy and well controllable.

1. Method of manufacturing a semiconductor device with a substrate and a semiconductor body which is provided with at least one semiconductor element and comprising a monocrystalline silicon region on top of which an epitaxial silicon region is formed by providing a metal silicide region on the monocrystalline silicon region and a low-crystallinity silicon region on top of the metal silicide region, after which the low-crystallinity silicon region is transformed by heating into the epitaxial silicon region having a high-crystallinity, during which process the metal silicide region is moved from the bottom of the low-crystallinity silicon region to the top of the epitaxial silicon region characterized in that above the level of the metal silicide region an insulating layer is formed which is provided with an opening the low-crystallinity silicon region is deposited in the opening and on top of the insulating layer the part of the low-crystallinity silicon region on top of the insulating layer is removed by a planarization process after which the epitaxial silicon region is formed.

2. Method according to claim 1, characterized in that the metal silicide region is formed by depositing a metal region at the location of the metal silicide region to be formed which subsequently is transformed in a heating process in the metal silicide region by reacting with the underlying silicon.

3. Method according to claim 2, characterized in that the metal region formed by deposition of a metal layer after the formation of the insulating layer provided with the opening and after formation of the metal silicide region the bottom of the opening, the remainder of the metal layer is removed by etching, preferably by selective etching.

4. Method according to claim 1, characterized in that the size of the opening in the insulating layer is chosen such that the epitaxial silicon region forms a nano-wire.

5. Method according to claim 1, characterized in that the epitaxial silicon region is formed as a part of the semiconductor element.

6. Method according to claim 5, characterized in that for the semiconductor element a field effect transistor is chosen, and that the epitaxial silicon region is used to form contact regions on top of the source and drain regions of the field effect transistor.

7. Method according to claim 5, characterized in that the semiconductor element is chosen to be a bipolar transistor and in that the epitaxial silicon region is used to form an emitter region or collector region of the bipolar transistor.

8. Method according to any claim 1, characterized in that for the metal nickel or cobalt is chosen.

9. Method according to claim 1, characterized in that the opening is formed by e-beam lithography and dry etching.

10. Method according to claim 1, characterized in that for the planarization process chemical-mechanical polishing is used.

11. Semiconductor device obtained by a method according to claim 1.
